(19) United States
(12) Patent Application Publication
(10) Pub. No.: US 2017/0256745 A1
(43) Pub. Date: Sep. 7, 2017

(54) METHOD FOR MANUFACTURING LIGHT EXTRACTION SUBSTRATE FOR ORGANIC LIGHT-EMITTING DIODE, LIGHT EXTRACTION SUBSTRATE FOR ORGANIC LIGHT-EMITTING DIODE, AND ORGANIC LIGHT-EMITTING DIODE INCLUDING SAME

(71) Applicant: Corning Precision Materials Co., Ltd., Chungcheongnam-do (KR)

(72) Inventors: Eun Ho Choi, Chungcheongnam-do (KR); Seo Hyun Kim, Chungcheongnam-do (KR); Joo Young Lee, Chungcheongnam-do (KR); Dong Hyun Kim, Chungcheongnam-do (KR); Eui Soo Kim, Chungcheongnam-do (KR)

(73) Assignee: Corning Precision Materials Co., Ltd., Chungcheongnam-do (KR)

(21) Appl. No.: 15/508,715

(22) PCT Filed: Sep. 3, 2015
(86) PCT No.: PCT/KR2015/009273

§ 371 Date: Mar. 3, 2017

(30) Foreign Application Priority Data
Sep. 5, 2014 (KR) 10-2014-0118894

(51) Int. Cl. H01L 51/52; B03C 1/015; H01F 41/30; H01F 1/00; H01L 51/56; H01F 41/24

(52) U.S. Cl. CPC H01L 51/5268; H01L 51/56; H01L 51/5215; H01F 41/24; H01F 41/30; H01F 1/0045; B03C 1/015; H01L 2251/303

(57) ABSTRACT

The present invention relates to a method for manufacturing a light extraction substrate for an organic light-emitting diode and, more specifically, to a method for manufacturing a light extraction substrate for an organic light-emitting diode, capable of increasing light extraction efficiency and structural stability of an organic light-emitting diode by improving the dispersibility of light scattering particles, distributed inside a matrix layer, and substrate adhesion. To this end, the present invention provides a method for manufacturing a light extraction substrate for an organic light-emitting diode, the method comprising: a first mixing step of mixing transparent magnetic nanoparticles with a volatile first solution; a second mixing step of mixing, with a second solution including nonmagnetic oxide particles, a mixed liquid formed through the first mixing step and light scattered particles; a coating step of coating a base substrate with a coating solution formed through the second mixing step; and a magnetic field application step of applying a magnetic field to the coating solution side on the lower part of the base substrate so as to magnetically align the transparent magnetic nanoparticles included inside the coating solution.

### TECHNICAL FIELD

The present disclosure relates to a method of manufacturing a light extraction substrate for an organic light-emitting diode (OLED) device. More particularly, the present disclosure relates to a method of manufacturing a light extraction substrate for an OLED device, in which the light extraction efficiency and structural reliability of an OLED device can be increased by improved dispersibility and substrate adhesion of light scattering particles distributed in a matrix layer.

### BACKGROUND ART

In general, light-emitting devices may be divided into organic light-emitting diode (OLED) devices having a light-emitting layer formed from an organic material and inorganic light-emitting devices having a light-emitting layer formed from an inorganic material. In OLED devices, OLEDs are self-emitting light sources based on the radiative decay of excitons generated in an organic light-emitting layer by the recombination of electrons injected through an electron injection electrode (cathode) and holes injected through a hole injection electrode (anode). OLEDs have a range of merits, such as low-voltage driving, self-emission, a wide viewing angle, high resolution, natural color reproducibility, and rapid response times.

Recently, research has been actively undertaken into applying OLEDs to portable information devices, cameras, watches, office equipment, information display devices for vehicles or the like, televisions (TVs), display devices, lighting systems, and the like.

To improve the luminous efficiency of such above-described OLED devices, it is necessary to improve the luminous efficiency of a material from which a light-emitting layer is formed or light extraction efficiency, i.e. efficiency at which light generated by the light-emitting layer is extracted.

The light extraction efficiency of an OLED device depends on the refractive indices of OLED layers. In a typical OLED device, when a beam of light generated by the light-emitting layer is emitted at an angle greater than a critical angle, the beam of light may be totally reflected at the interface between a higher-refractivity layer, such as a transparent electrode layer acting as an anode, and a lower-refractivity layer, such as a glass substrate. This may consequently lower light extraction efficiency, thereby lowering the overall luminous efficiency of the OLED device, which is problematic.

Described in more detail, only about 20% of light generated by an OLED is emitted from the OLED device and about 80% of the light generated is lost due to a waveguide effect originating from different refractive indices of a glass substrate, an anode, and an organic light-emitting layer comprised of a hole injection layer, a hole transport layer, an emissive layer, an electron transport layer, and an electron injection layer, as well as by the total internal reflection originating from the difference in refractive indices between the glass substrate and ambient air. Here, the refractive index of the internal organic light-emitting layer ranges from 1.7 to 1.8, whereas the refractive index of indium tin oxide (ITO), generally used in anodes, is about 1.9. Since the two layers have a significantly low thickness, ranging from 200 nm to 400 nm, and the refractive index of the glass used for the glass substrate is about 1.5, a planar waveguide is thereby formed inside the OLED device. It is calculated that the ratio of the light lost in the internal waveguide mode due to the above-described reason is about 45%. In addition, since the refractive index of the glass substrate is about 1.5 and the refractive index of the ambient air is 1.0, when light exits the interior of the glass substrate, a beam of the light, having an angle of incidence greater than a critical angle, is totally reflected and trapped inside the glass substrate. The ratio of trapped light is about 35%, and only about 20% of generated light may be emitted from the OLED device.

To overcome such problems, light extraction layers through which 80% of light that would otherwise be lost in the internal waveguide mode can be extracted have been actively researched. Light extraction layers are generally categorized as internal light extraction layers and external light extraction layers. In case of external light extraction layers, it is possible to improve light extraction efficiency by disposing a film including micro-lenses on the outer surface of the substrate, the shape of the micro-lenses being selected from a variety of shapes. The improvement of light extraction efficiency does not significantly depend on the shape of micro-lenses. On the other hand, internal light extraction layers directly extract light that would otherwise be lost in the light waveguide mode. Thus, the possibility of internal light extraction layers to improve light extraction efficiency may be higher than that of external light extraction layers. However, an internal light extraction layer may act contrary to this intention, when the angle of incident light is substantially perpendicular to the glass substrate. Although an internal light extraction layer may have higher light extraction efficiency than an external light extraction layer, such an internal light extraction layer may cause light loss. In addition, an internal light extraction layer must be formed during the fabrication process of an OLED device, is influenced by subsequent processing, and is difficult to form in technological terms, which are problematic.

In technological terms, it is typical to coat a substrate with a light-scattering layer containing light-scattering particles. Specifically, metal oxide particles may be used as light-scattering particles distributed in a matrix to obtain a refractive index difference and a light scattering effect at the boundaries of the metal oxide particles. However, according to such a conventional method, the clustering of the light-scattering particles may reduce dispersibility, thereby reducing the light extraction effect. In addition, this may consequently degrade surface roughness characteristics, thereby reducing the lifetime and reliability of an OLED device, which are problematic. Furthermore, conventionally, voids formed between the spherical light-scattering particles reduce adhesion between the light-scattering particles and the substrate. This feature may render subsequent processing difficult.

### RELATED ART DOCUMENT

Korean Patent No. 1093259 (Dec. 6, 2011)

### DISCLOSURE

### Technical Problem

Accordingly, the present disclosure has been made in consideration of the above problems occurring in the related art, and the present disclosure proposes a method of manufacturing a light extraction substrate for an organic light-emitting diode (OLED) device, in which the light extraction efficiency and structural reliability of an OLED device can be increased by improved dispersibility and substrate adhesion of light scattering particles distributed in a matrix layer.

### Technical Solution

According to an aspect of the present disclosure, a method of fabricating a light extraction substrate for an OLED device may include: preparing a mixture solution by mixing transparent magnetic nanoparticles with a volatile first solution; preparing a coating solution by mixing the mixture solution and light-scattering particles with a second solution containing nonmagnetic oxide particles; coating a base substrate with the coating solution; and magnetically aligning the transparent magnetic nanoparticles contained in the coating solution by applying a magnetic field in a direction from below the base substrate to the coating solution.

The transparent magnetic nanoparticles may be Ti₁₋ₓMₓO₂.

In Ti₁₋ₓMₓO₂, M may be Co or Ni.

In Ti₁₋ₓMₓO₂, x may range from 0.1 to 0.5.

In Ti₁₋ₓMₓO₂, x may be 0.2.

The light-scattering particles may be formed from a material, a refractive index of which differs from a refractive index of the nonmagnetic oxide particles by 0.3 or greater.

Coating the base substrate with the coating solution and applying the magnetic field may be performed simultaneously.

The magnetic field may be applied in the direction of the coating solution by moving a magnetic field generator in a direction in which the coating solution is applied to the base substrate.

After the base substrate is coated, adjacent light-scattering particles of the light-scattering particles may be clustered together to form a number of light-scattering particle clusters which each are in contact with a surface of the base substrate, and a number of transparent magnetic nanoparticles of the transparent magnetic nanoparticles and a number of nonmagnetic oxide particles of the nonmagnetic oxide particles may be irregularly attached to surfaces of the number of light-scattering particle clusters.

After the magnetic field is applied, the number of transparent magnetic nanoparticles may penetrate between the adjacent light-scattering particles and into voids formed by the base substrate and the adjacent light-scattering particles.

The method may further include firing the coating solution after applying the magnetic field.

When the coating solution is fired, a structure in which the light-scattering particles and the transparent magnetic nanoparticles are distributed within the matrix layer composed of the nonmagnetic oxide particles may be made.

The matrix layer may face a transparent electrode of an organic light-emitting diode device.

### Advantageous Effects

According to the present disclosure, in response to a magnetic field being applied in a direction from below a base substrate to a coating solution, a number of transparent magnetic nanoparticles are magnetically aligned, thereby causing clustered light-scattering particles to be separated from each other. This can consequently improve the dispersibility of the light-scattering particles distributed in a light extraction layer, thereby improving the light extraction efficiency of an OLED device.

In addition, according to the present disclosure, in response to the magnetic field being applied in the direction from below the base substrate to the coating solution, the number of transparent magnetic nanoparticles are magnetically aligned in a structure in which voids formed by light-scattering particles and the base substrate are filled. This can consequently improve adhesion between the light extraction layer and the base substrate, thereby improving the structural reliability of a light extraction substrate. Furthermore, when the light extraction substrate is disposed on a side of an OLED device, through which light generated by the OLED exits, the reliability of the OLED device can be improved.

### DESCRIPTION OF DRAWINGS

FIG. 1 is a process flowchart illustrating a method of manufacturing a light extraction substrate for an OLED device according to an embodiment of the present disclosure; and

FIG. 2 and FIG. 3 are conceptual views illustrating the arrangement of transparent magnetic nanoparticles before and after the application of a magnetic field in the method of manufacturing a light extraction substrate for an OLED device according to the embodiment of the present disclosure.

### MODE FOR INVENTION

Hereinafter, a method of manufacturing a light extraction substrate for an organic light-emitting diode (OLED) device according to an embodiment of the present disclosure will be described in detail with reference to the accompanying drawings.

In the following description, detailed descriptions of known functions and components incorporated herein will be omitted in the case that the subject matter of the present disclosure may be rendered unclear by the inclusion thereof.

The method of manufacturing a light extraction substrate for an OLED device according to an embodiment of the present disclosure is a method of manufacturing a light extraction substrate 100 that is provided in a portion of an OLED device, through which light generated by the OLED exits, to improve the light extraction efficiency of the OLED device.

Although not shown, the OLED device includes the light extraction substrate 100 manufactured according to the embodiment of the present disclosure and a multilayer structure sandwiched between the light extraction substrate and an encapsulation substrate facing the light extraction substrate. The multilayer structure is comprised of an anode, an organic light-emitting layer, and a cathode. The anode is a transparent electrode provided to face the light extraction substrate 100 manufactured according to the embodiment of the present disclosure. The anode may be formed form a metal, such as Au, In, or Sn, or a metal oxide, such as indium tin oxide (ITO), that has a greater work function to facilitate hole injection. The cathode may be a metal thin film formed from Al, Al:Li, or Mg:Ag that has a smaller work function to facilitate electron injection. In addition, the organic light-emitting layer may include a hole injection layer, a hole transport layer, an emissive layer, an electron transport layer, and an electron injection layer that are sequentially stacked on the anode.

According to this structure, when a forward voltage is induced between the anode and the cathode, electrons migrate from the cathode to the emissive layer through the electron injection layer and the electron transport layer, while holes migrate from the anode to the emission layer through the hole injection layer and the hole transport layer. The electrons and the holes that have migrated into the emission layer recombine with each other, thereby generating excitons. When these excitons transit from an excited state to a grounded state, light is emitted. The brightness of the emitted light is proportional to the amount of current flowing between the anode and the cathode.

When the OLED device is a white OLED device used for lighting, the organic light-emitting layer may have, for example, a multilayer structure including a high-molecular light-emitting layer that emits blue light and a low-molecular light-emitting layer that emits orange-red light. In addition, a variety of other structures that emit white light may be used. In addition, the organic light-emitting layer may have a tandem structure. Specifically, a plurality of organic light-emitting layers alternating with interconnecting layers may be provided.

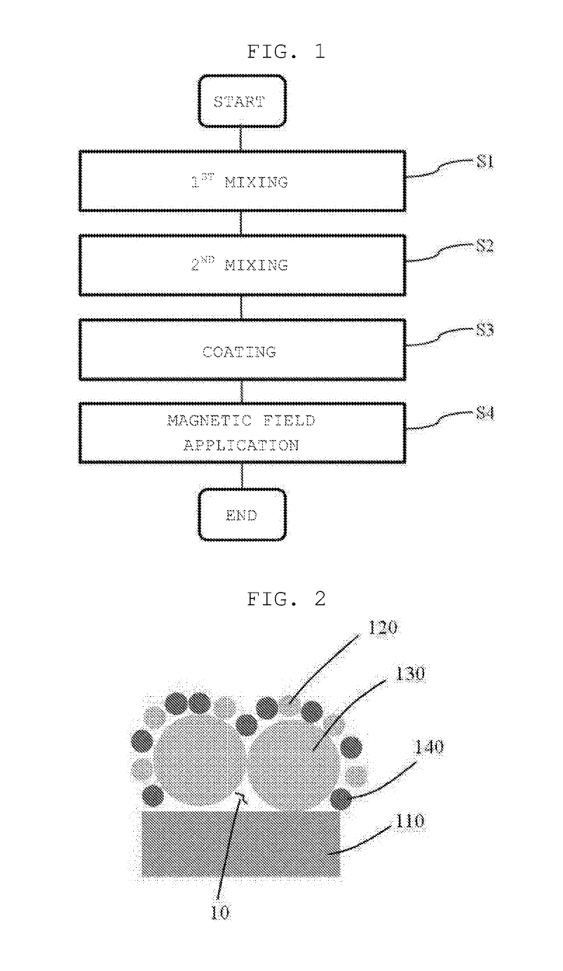

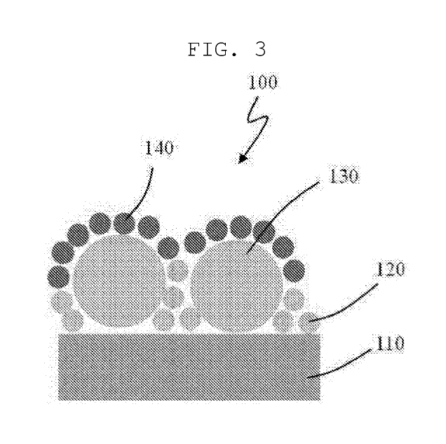

As illustrated in FIG. 1, the method of manufacturing a light extraction substrate for an OLED device according to the embodiment of the present disclosure, i.e. the method of manufacturing the light extraction substrate 100 used for the above-described OLED device, includes a first mixing step S1, a second mixing step S2, a coating step S3, and a magnetic field application step S4. Regarding reference numerals of the following components, FIG. 2 and FIG. 3 will be referred to.

First, the first mixing step S1 is a step of making a mixture solution by mixing nanoparticles with a first solution. To make the mixture solution, in the first mixing step S1, transparent magnetic nanoparticles 120 in a colloidal state are mixed with the volatile first solution, such as alcohol. The transparent magnetic nanoparticles 120 mixed with the first solution may be Ti₁₋ₓMₓO₂. Here, M may be Co or Ni. In addition, x may range from 0.1 to 0.5, and preferably, may be 0.2. According to the embodiment of the present disclosure, Ti_{0.8}Co_{0.2}O₂ may be used as the transparent nanoparticles 120. Ti_{0.8}Co_{0.2}O₂ is a ferromagnetic material that has a magneto-optical effect in a wavelength range of 280 nm to 380 nm and does not interfere with visible light.

Subsequently, the second mixing step S2 is a step of mixing the mixture solution made in the first mixing step S1 and light-scattering particles 130 with a second solution. Here, the second solution is a solution containing nonmagnetic oxide particles 140 that are applied to a base substrate 110 in a subsequent process to form a matrix layer for the transparent magnetic nanoparticles 120 and the light-scattering particles 130. That is, the second mixing step S2 is a step of making a coating solution supposed to form a light extraction layer for the OLED device by mixing the mixture solution containing the transparent magnetic nanoparticles 120, the light-scattering particles 130, and the second solution containing the nonmagnetic oxide particles 140 together. Here, the light-scattering particles 130 and the nonmagnetic oxide particles 140 acting as the matrix layer for the light-scattering particles 130 must have different refractive indices to be used for the light extraction layer of the OLED device. In this regard, in the second mixing step S2, a material, the refractive index of which differs from the refractive index of the nonmagnetic oxide particles 140 by 0.3 or greater, may be used for the light-scattering particles 130. For example, when silica, titania, or the like is used for the light-scattering particles 130, a metal oxide, the refractive index of which differs from the refractive index of the light-scattering particles 130 by 0.3 or greater, may be used for the nonmagnetic oxide particles 140 that are supposed to form the matrix layer for the light-scattering particles 130. When the difference of the refractive index of the light-scattering particles 130 from the refractive index of the matrix layer composed of the nonmagnetic oxide particles 140 is 0.3 or greater as described above, an internal light extraction layer comprised of the light-scattering particles 130 and the matrix layer having different refractive indices is formed between the OLED and the base substrate 110. This structure can reduce total internal reflection that would conventionally be caused at the interface between the glass substrate and the OLED while disturbing a waveguide mode formed at the interface, thereby significantly improving the light extraction efficiency of the OLED device.

Next, the coating step S3 is a step of coating the base substrate 110 with the coating solution that is supposed to form the light extraction layer. In the coating step S3, a surface of the base substrate 110 is coated with the coating solution containing the transparent magnetic nanoparticles 120, the light-scattering particles 130, and the nonmagnetic oxide particles 140.

FIG. 2 is a conceptual view schematically illustrating the arrangement of the transparent magnetic nanoparticles 120, the light-scattering particles 130, and the nonmagnetic oxide particles 140 after the coating step S3 was performed. As illustrated in FIG. 2, after the coating step S3, a number of light-scattering particles 130 may be in contact with the surface of the base substrate 110 due to the gravity-induced downward migration thereof within the matrix layer composed of the nonmagnetic oxide particles 140. Here, the number of light-scattering particles 130 which are adjacent to each other may be clustered. Such clustering of the number of light-scattering particles 130 is a factor that reduces the surface roughness and light extraction efficiency of the light extraction layer. In addition, without any further processing, voids 10 are formed between the number of spherical light-scattering particles 130 and the base substrate 110. The voids 10 are a factor that reduces the interfacial adhesion between the base substrate 110 and the light extraction layer. Specifically, directly after the base substrate 110 is coated with the light-scattering particles 130 and the nonmagnetic oxide particles 140 that are supposed to form the matrix layer for the light-scattering particles 130, the initial structure of the light extraction layer comprised of the light-scattering particles 130 and the nonmagnetic oxide particles 140 is unsuitable for obtaining superior light extraction efficiency and adhesion.

After the completion of the coating step S3, a number of transparent magnetic nanoparticles 120 and a number of nonmagnetic oxide particles 140 remain in close contact with each other due to Van der Waals attraction acting between the particles or electromagnetic attraction. Such attraction acts not only between the number of transparent magnetic nanoparticles 120 and the number of nonmagnetic oxide particles 140 but also between the particles 120 and 140 and the number of light-scattering particles 130. Due to the number of light-scattering particles 130 clustered together, a structure in which the number of transparent magnetic nanoparticles 120 and the number of nonmagnetic oxide particles 140 are attached to the cluster of the number of light-scattering particles 130 is made. That is, the number of transparent magnetic nanoparticles 120 and the number of nonmagnetic oxide particles 140 are attached to the surfaces of the cluster of the number of light-scattering particles 130, except for the surfaces of the number of light-scattering particles 130 that are in contact with each other. Here, the number of transparent magnetic nanoparticles 120 and the number of nonmagnetic oxide particles 140 are irregularly arranged.

The base substrate 110 coated with the coating solution containing the transparent magnetic nanoparticles 120, the light-scattering particles 130, and the nonmagnetic oxide particles 140 is a transparent substrate that may be formed from any material having superior light transmittance and mechanical properties. For example, the base substrate 110 may be formed from a polymeric material, such as a thermally or ultraviolet (UV) curable organic film. Alternatively, the base substrate 110 may be formed from chemically strengthened glass, such as soda-lime glass (Si0₂—CaO—Na₂O) or aluminosilicate glass (SiO₂—Al₂O₃—Na₂O). When the OLED device including the light extraction substrate according to the embodiment of the present disclosure is used for lighting, the base substrate 110 may be formed from soda-lime glass. In addition, the base substrate 110 may also be a metal oxide substrate or a metal nitride substrate. According to the embodiment of the present disclosure, the base substrate 110 may be a thin glass substrate having a thickness of 1.5 mm or less. The thin glass substrate may be fabricated using a fusion process or a floating process.

Finally, the magnetic field application step S4 is a step of magnetically aligning the number of transparent magnetic nanoparticles 120 irregularly attached to the surfaces of the number of light-scattering particles 130. In this regard, in the magnetic field application step S4, a magnetic field is applied in the direction from below the base substrate 110 to the coating solution coating the base substrate 110.

In this case, according to the embodiment of the present disclosure, the coating step S3 and the magnetic field application step S4 may be performed simultaneously. Specifically, while the base substrate 110 is being coated with the coating solution, a magnetic field may be sequentially applied in the direction of the coating solution, for example, by moving a magnetic field generator in the direction in which the coating solution is applied. Alternatively, depending on the coating method, a magnetic field may be sequentially applied in the direction of the coating solution by moving the base substrate 110.

When a magnetic field is applied in the direction from below the base substrate 110 to the coating solution containing the transparent magnetic nanoparticles 120 in the magnetic field application step S4 as described above, as illustrated in FIG. 3, the transparent magnetic nanoparticles 120 penetrate between the number of clustered light-scattering particles 130 through migration and re-arrangement due to magnetic polarities, thereby causing the light-scattering particles 130 to be separated from each other. Consequently, the dispersibility of the light-scattering particles 130 is improved. In addition, in this case, the voids 10 formed by the base substrate 110 and the adjacent light-scattering particles 130 are filled by the transparent magnetic nanoparticles 120 that have been magnetically aligned, i.e. moved in the direction of the base substrate 110. Consequently, the interfacial adhesion between the light extraction layer comprised of the light-scattering particles 130 and the nonmagnetic oxide particles 140 and the base substrate 110 is improved.

In addition, in response to the application of the magnetic field, unoccupied sites from which the transparent magnetic nanoparticles 120 moved away are filled by some of the remaining nonmagnetic oxide particles 140 of the matrix layer that are drawn due to Van der Waals attraction.

After the magnetic field application step S4, the coating solution is subjected to a firing process to convert the liquid-state coating solution applied on the base substrate 110 into a solid-state light extraction layer. Here, as discussed in the embodiment of the present disclosure, when the light extraction layer is formed by wet coating, the thickness of the matrix layer composed of the nonmagnetic oxide particles 140 is reduced in response to the firing of the coating solution. In this case, the light-scattering particles 130 may increase the surface roughness of the matrix layer. When the matrix layer having the high surface roughness as described above is brought into contact with a transparent electrode acting as an anode of an OLED or has a transparent electrode of an OLED formed thereon, the surface structure of the matrix layer may be transferred to the transparent electrode, thereby degrading the electrical characteristics of the OLED. In other words, the surface of the matrix layer to be in contact with the transparent electrode must be a high flat surface so that the matrix layer is qualified as the internal light extraction layer of the OLED device. Accordingly, a process of forming a planarization layer on the light extraction layer may be added.

The foregoing descriptions of specific exemplary embodiments of the present disclosure have been presented with respect to the drawings. They are not intended to be exhaustive or to limit the present disclosure to the precise forms disclosed, and obviously many modifications and variations are possible for a person having ordinary skill in the art in light of the above teachings.

It is intended therefore that the scope of the present disclosure not be limited to the foregoing embodiments, but be defined by the Claims appended hereto and their equivalents.

1. A method of fabricating a light extraction substrate for an organic light-emitting diode device, the method comprising:
preparing a mixture solution by mixing transparent magnetic nanoparticles with a volatile first solution;
preparing a coating solution by mixing the mixture solution and light-scattering particles with a second solution containing nonmagnetic oxide particles;
coating a base substrate with the coating solution; and
magnetically aligning the transparent magnetic nanoparticles contained in the coating solution by applying a magnetic field in a direction from below the base substrate to the coating solution.

2. The method of claim 1, wherein the transparent magnetic nanoparticles comprise Ti₁₋ₓMₓO₂.

3. The method of claim 2, wherein M is Co or Ni.

4. The method of claim 2, wherein x ranges from 0.1 to 0.5.

5. The method of claim 4, wherein x is 0.2.

6. The method of claim 1, wherein the light-scattering particles comprise a material, a refractive index of which differs from a refractive index of the nonmagnetic oxide particles by 0.3 or greater.

7. The method of claim 1, wherein coating the base substrate with the coating solution and applying the magnetic field are performed simultaneously.

8. The method of claim 7, wherein the magnetic field is applied in the direction of the coating solution by moving a magnetic field generator in a direction in which the coating solution is applied to the base substrate.

9. The method of claim 1, wherein, after the base substrate is coated, adjacent light-scattering particles of the light-scattering particles are clustered together to form a number of light-scattering particle clusters which each are in contact with a surface of the base substrate, and a number of transparent magnetic nanoparticles of the transparent magnetic nanoparticles and a number of nonmagnetic oxide particles of the nonmagnetic oxide particles are irregularly attached to surfaces of the number of light-scattering particle clusters.

10. The method of claim 9, wherein, after the magnetic field is applied, the number of transparent magnetic nanoparticles penetrate between the adjacent light-scattering particles and into voids formed by the base substrate and the adjacent light-scattering particles.

11. The method of claim 1, further comprising firing the coating solution after applying the magnetic field.

12. The method of claim 11, wherein, when the coating solution is fired, a structure in which the light-scattering particles and the transparent magnetic nanoparticles are distributed within the matrix layer composed of the nonmagnetic oxide particles is made.

13. The method of claim 12, wherein the matrix layer faces a transparent electrode of an organic light-emitting diode device.

14-15. (canceled)
